(19) United States
(12) Patent Application Publication
(10) Pub. No.: US 2018/0337630 A1
(43) Pub. Date: Nov. 22, 2018

(54) INSULATING GLAZING UNIT WITH PHOTOVOLTAIC POWER SOURCE

(71) Applicant: Andersen Corporation, Bayport, MN (US)

(72) Inventors: David D. Plummer, Hudson, WI (US); Chad Wernlund, Baldwin, WI (US); Jacob Lutz, Stillwater, MN (US)

(21) Appl. No.: 15/980,912

(22) Filed: May 16, 2018

Related U.S. Application Data
(60) Provisional application No. 62/507,864, filed on May 18, 2017.

(51) Int. Cl. H02S 20/26; H01L 31/048; E06B 3/663

(52) U.S. Cl. CPC H02S 20/26; E06B 3/66309; H01L 31/0488

(57) ABSTRACT

Embodiments include insulating glazing units with a photovoltaic cell structure disposed within and related methods. In some embodiments, the insulating glazing unit can include a first transparent pane and a second transparent pane. The insulating glazing unit can further include an internal space disposed between the first and second transparent panes and a spacer unit disposed between the first and second transparent panes. The spacer unit can be disposed adjacent to the perimeter of the first transparent pane and the second transparent pane. The spacer unit can have an inward surface facing the internal space. A photovoltaic cell structure can be disposed between the first and second transparent panes. The photovoltaic cell structure can be disposed over at least a portion of the inward surface of the spacer unit. The photovoltaic cell structure can include a photovoltaically active surface facing the internal space. Other embodiments are also included herein.

This application claims the benefit of U.S. Provisional Application No. 62/507,864, filed May 18, 2017, the content of which is herein incorporated by reference in its entirety.

### FIELD

Embodiments herein relate to insulating glazing units. More specifically, embodiments herein relate to insulating glazing units with a photovoltaic cell structure disposed within.

### BACKGROUND

Glazing units frequently include two or more sheets of glass separated from one another by a space. The space (or insulating space) in between the sheets of glass can be filled with a gas (such as air, argon, krypton or xenon) to enhance insulating properties. A window spacer assembly is a structure that is frequently disposed between the sheets of glass around the periphery.

Glazing units are frequently disposed within a frame or other structure forming a window, door, skylight or other construction component.

While some windows and doors containing glazing units are mounted within the interior of a structure and thus receive relatively little sunlight, most are disposed within exterior walls of structures so as to receive substantial amounts of sunlight.

### SUMMARY

Various embodiments disclosed herein provide an insulating glazing unit. The insulating glazing unit can include a first transparent pane and a second transparent pane. The insulating glazing unit can further include an internal space disposed between the first and second transparent panes and a spacer unit disposed between the first and second transparent panes. The spacer unit can be disposed adjacent to the perimeter of the first transparent pane and the second transparent pane. The spacer unit can have an inward surface facing the internal space. A photovoltaic cell structure can be disposed between the first and second transparent panes. The photovoltaic cell structure can be disposed over the inward surface of the spacer unit, or at least some portion thereof. The photovoltaic cell structure can include a photovoltaically active surface facing the internal space.

In various embodiments, the insulating glazing unit can include a top, a bottom, a first side and a second side. The photovoltaic cell structure can include a top portion adjacent the top of the insulating glazing unit, a bottom portion adjacent the bottom of the insulating glazing unit, a first side portion adjacent the first side of the insulating glazing unit, and a second side portion adjacent the second side of the insulating glazing unit.

In various embodiments, the photovoltaic cell structure can include a plurality of discrete photovoltaic cells.

In various embodiments, the photovoltaic cell structure can be disposed on the inward surface of the spacer unit oriented with the photovoltaically active surface substantially perpendicular to the first transparent pane and the second parent pane.

In various embodiments, the photovoltaic cell structure can be disposed on the inward surface of the spacer unit oriented with the photovoltaically active surface both non-perpendicular and non-parallel to the first transparent pane and the second transparent pane.

In various embodiments, the photovoltaic cell structure can be disposed substantially equidistantly from the first and second transparent panes.

In various embodiments, the photovoltaic cell structure can be disposed closer to one of the first and second transparent panes than the other.

In various embodiments, the plurality of discrete photovoltaic cells are responsive to wavelengths of light between 380 nm and 750 nm.

In various embodiments, the plurality of discrete photovoltaic cells are responsive to wavelengths of light below 380 nm and above 750 nm.

In various embodiments, the photovoltaic cell structure is porous to the passage of water vapor.

In various embodiments, the photovoltaic cell structure can include a plurality of apertures to allow the passage of water vapor there through.

In various embodiments, the plurality of apertures disposed along a center of the spacer unit.

In various embodiments, the photovoltaic cell structure can include lateral cutouts.

In various embodiments, the photovoltaic cell structure can include scalloped side edges.

In various embodiments, the photovoltaic cell structure is flexible.

In various embodiments, the photovoltaic cell structure can be bent to a radius of curvature of 1 cm or less without damage.

In various embodiments, the photovoltaic cell structure is attached, directly or indirectly, to the inward surface of the spacer unit. The photovoltaic cell structure can be attached with an adhesive layer or through other techniques such as clips, brackets, screws, standoffs, posts, tabs, bolts or other fasteners, welding (spot, ultrasonic, thermal, etc.), direct deposition or printing, and the like.

In various embodiments, the photovoltaic cell structure can include a flexible substrate. The flexible substrate can be attached to the inward surface of the spacer unit. However, it will be appreciated that in some embodiments the photovoltaic cell structure may lack a flexible substrate and/or may lack any kind of substrate. In some embodiments the photovoltaic cell structure may only include photovoltaic cells and electrical conductors to convey current generated thereby.

In various embodiments, the photovoltaic cell structure can further include a flexible substrate. The flexible substrate can be attached to the inward surface of the spacer unit with an adhesive layer. However, in other embodiments, the flexible substrate can be omitted and the other components of the photovoltaic cell structure can be directly or indirectly attached to the inward surface of the spacer unit with an adhesive layer or through other techniques such as clips, brackets, screws, standoffs, posts, tabs, bolts or other fasteners, welding (spot, ultrasonic, thermal, etc.), direct deposition or printing, and the like.

In various embodiments, the photovoltaic cell structure can be attached to the inward surface of the spacer unit with a clip.

In various embodiments, the insulating glazing unit can further include a frame disposed within the internal space and arranged between the spacer unit and the photovoltaic cell structure. The photovoltaic cell structure can be supported by the frame.

In various embodiments, the insulating glazing unit can further include a joining member (or coupler). The joining member can serve to connect two ends of the spacer unit together. The joining member can also serve as a conduit to provide for the passage of an electrical conductor(s) thereby providing electrical communication between the photovoltaic cell structure and an area outside the spacer unit. In some embodiments the joining member can specifically be a corner key that can be connected to a corner of the spacer unit. The corner key can be connected to a first and second electrical conductor providing electrical communication between the photovoltaic cell structure and an area outside the spacer unit.

Various embodiments provide a fenestration unit. The fenestration unit can include an insulating glazing unit mounted within a frame. The insulating glazing unit can include a first transparent pane; a second transparent pane; an internal space disposed between the first and second transparent panes; a spacer unit disposed between the first and second transparent panes, and a photovoltaic cell structure. The spacer unit can be disposed adjacent the perimeter of the first transparent pane and the second transparent pane. The spacer unit can have an inward surface facing the internal space. The photovoltaic cell structure can be disposed between the first and second transparent panes. The photovoltaic cell structure can be disposed over the inward surface of the spacer unit or at least some portion thereof. The photovoltaic cell structure can include a photovoltaically active surface facing the internal space.

This summary is an overview of some of the teachings of the present application and is not intended to be an exclusive or exhaustive treatment of the present subject matter. Further details are found in the detailed description and appended claims. Other aspects will be apparent to persons skilled in the art upon reading and understanding the following detailed description and viewing the drawings that form a part thereof, each of which is not to be taken in a limiting sense. The scope herein is defined by the appended claims and their legal equivalents.

### BRIEF DESCRIPTION OF THE FIGURES

Aspects may be more completely understood in connection with the following figures, in which:

FIG. 1 is a perspective partial cutaway view of an insulating glazing unit, according to various embodiments.

FIG. 2 is a front view of the insulating glazing unit shown in FIG. 1.

FIG. 3 is a cross-sectional view of an insulating glazing unit taken along line 3-3′ in FIG. 2, according to various embodiments.

FIG. 4 is a cross-sectional view of an insulating glazing unit according to various embodiments.

FIG. 5 is a cross-sectional view of an insulating glazing unit according to various embodiments.

FIG. 6 is a cross-sectional view of an insulating glazing unit according to various embodiments.

FIG. 7 is a cross-sectional view of an insulating glazing unit according to various embodiments.

FIG. 8 is a front view of a spacer, according to various embodiments.

FIG. 9 is a top view of a photovoltaic cell structure, according to various embodiments.

FIG. 10 is a cross-sectional view of a portion of an insulating glazing unit, according to various embodiments.

FIG. 11 is a cross-sectional view of a portion of an insulating glazing unit, according to various embodiments.

FIG. 12 is a cross-sectional view of a portion of an insulating glazing unit, according to various embodiments.

FIG. 13 is a top view of a photovoltaic cell structure, according to various embodiments.

FIG. 14 is a top view of a photovoltaic cell structure, according to various embodiments.

FIG. 15 is a cross-sectional view of a portion of an insulating glazing unit, according to various embodiments.

FIG. 16 is a cross-sectional view of a portion of an insulating glazing unit, according to various embodiments.

FIG. 17 is a cross-sectional view of a portion of an insulating glazing unit, according to various embodiments.

FIG. 18 is a cross-sectional view of a portion of an insulating glazing unit, according to various embodiments.

FIG. 19 is a front view of a spacer and photovoltaic cell structure, according to various embodiments.

FIG. 20 is a front view of a spacer, according to various embodiments.

FIG. 21 is a schematic diagram of one embodiment of how electricity can be delivered to a power demanding component within an IGU.

While embodiments are susceptible to various modifications and alternative forms, specifics thereof have been shown by way of example and drawings, and will be described in detail. It should be understood, however, that the scope herein is not limited to the particular embodiments described. On the contrary, the intention is to cover modifications, equivalents, and alternatives falling within the spirit and scope herein.

### DETAILED DESCRIPTION

In recent years electrically operated devices have been incorporated into insulating glazing units and/or the products they are incorporated into. The electrically operated devices can have various different purposes. In some implementations the electrically operated devices are used to control light transmissions. In other implementations that devices can be used to connect the insulating glazing unit to a home automation or energy management system. Regardless of their intended purpose, these devices need to be supplied with electricity in order to function.

Various ways of powering these devices have been attempted such as a direct wire connection to a power source and connecting the devices to batteries. However, in some cases a power source is not readily available and batteries need to be recharged or replaced.

In various embodiments herein, insulating glazing units are provided with a photovoltaic cell structure within an interior space of the insulating glazing unit. The photovoltaic cell structure can include photovoltaic cells and can absorb light rays and convert the light rays to usable electricity. The photovoltaic cell structure can also include electrical conductors in order to convey electrical current generated by the photovoltaic cells. In some embodiments, the photovoltaic cells can be provided on an inward facing surface of the spacer unit.

The electricity generated by the photovoltaic cells can be used to power various components and/or charge batteries, amongst other functions. For example, the electricity generated by the photovoltaic cells can be used to power components within or adjacent to the IGU or within or adjacent to other components of a fenestration unit. Further examples of electrically powered components and details of the same are described below. In some embodiments, the photovoltaic cells can be electrically coupled to the components that demand power, such as to directly power the device from the photovoltaic cells. In some embodiments, the photovoltaic cells can be electrically coupled to one or more batteries. The batteries can then be used to power the components that demand power. In other embodiments, the photovoltaic cells can be used to directly power components and to charge batteries.

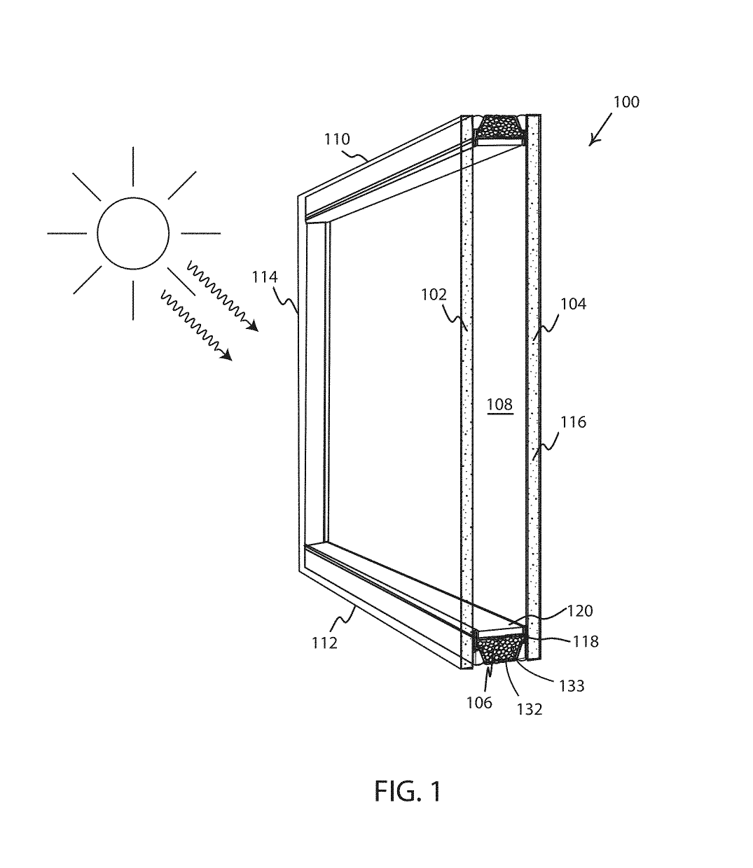

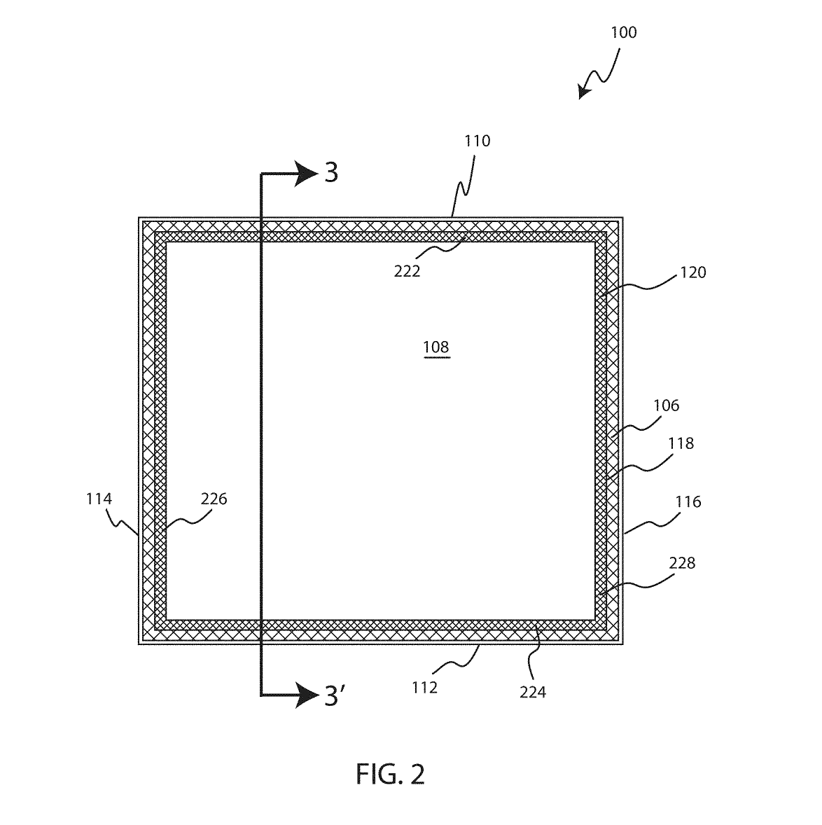

FIG. 1 shows a perspective partial cutaway view (with the portion closest to the foreground cutaway to show internal elements thereof) of an insulating glazing unit 100, according to various embodiments. FIG. 2 shows a front view of the insulating glazing unit 100. In various embodiments, the insulating glazing unit (“IGU”) 100 can include a first pane 102 and a second pane 104. The first pane 102 can be substantially parallel to the second pane 104. The first pane 102 and the second pane 104 can be transparent, such as to allow light to pass through the panes 102, 104.

A spacer unit 106 can be disposed between the first pane 102 and the second pane 104. In various embodiments, the panes 102, 104 can be adhesively bonded to the spacer unit 106. The spacer unit 106 can define a perimeter of an interior space 108 (or air space) between the first pane 102 and the second pane 104. The spacer unit 106 can be disposed adjacent to a perimeter of the first pane 102 and the second pane 104. The spacer unit 106 (aspects of which are described in greater detail below) can take on various constructions, but in some embodiments can be a metal structure that defines a rectangular cross-sectional profile. In other embodiments, the spacer unit 106 can comprise a polymeric material. The spacer unit 106 can define an inner area 132. In some embodiments, the inner area 132 can be at least partially filled with a desiccant 133 (described in greater detail below). The desiccant 133 can be a water vapor absorbing material, such as to absorb water vapor from the interior space 108.

The distance between the panes 102, 104 (e.g., the distance between interior surfaces of the panes) can be from about 3 millimeters to about 30 millimeters. In some embodiments, the distance between the panes 102, 104 can be about 3, 4, 5, 5.5, 6.5, 7, 7.5, 8, 8.5, 9, 9.5, 10, 10.5, 11, 11.5, 12, 12.2, 12.5, 13, 14, 14.5, 15, 16, 18, 24, or 30 millimeters. In some embodiments, the distance between the panes can be in a range wherein any of the foregoing distances can serve as the upper or lower bound of the range, provided that the upper bound is greater than the lower bound.

The IGU 100 can include a top 110, a bottom 112, a first side 114, and a second side 116. In various embodiments, the top 110 can be parallel with the bottom 112. In various embodiments, the first side 114 can be parallel with the second side 116. In various embodiments, the top 110 and bottom 112 can be perpendicular to the first side 114 and the second side 116.

The spacer unit 106 can include an inwardly facing surface or inward surface 118 that faces towards the interior space 108 (or air space). The inward surface 118, the first pane 102, and the second pane 104 can define the interior space 108. The inward surface 118 can be perpendicular to the first pane 102 or second pane 104. In other embodiments, the inward surface 118 can in a non-parallel non-perpendicular arrangement with the first pane 102 and the second pane 104.

In various embodiments of the IGU 100, a photovoltaic cell structure 120 can be disposed within the interior space 108. The photovoltaic cell structure 120 can be disposed over or on the inward surface 118 of the spacer unit 106 or at least some portion thereof. In some embodiments the photovoltaic cell structure 120 can be directly disposed on the inward surface 118 of the spacer unit 106 and in other embodiments there can be a gap between the inward surface 118 and the photovoltaic cell structure 120. In various embodiments, the photovoltaic cell structure 120 can be attached or coupled to the inward surface 118 of the spacer unit 106. The photovoltaic cell structure 120 can include a photovoltaically active surface facing towards the interior space 108.

As shown in FIG. 2, in various embodiments, the photovoltaic cell structure 120 can include a top portion 222, a bottom portion 224, a first side portion 226, and a second side portion 228. The top portion 222 can be adjacent to the top 110 of the IGU 100. The bottom portion 224 can be adjacent to the bottom 112 of the IGU 100. The first side portion 226 can be adjacent to the first side 114 of the IGU 100. The second side portion 228 can be adjacent to the second side 116 of the IGU 100. As previously mentioned, the photovoltaic cell structure 120 can be disposed over or on the inward surface 118 of the spacer unit 106 or at least some portion thereof. The length of the photovoltaic cell structure 120 or the perimeter defined by the photovoltaic cell structure 120 can be smaller than the length or perimeter defined by the inward surface 118.

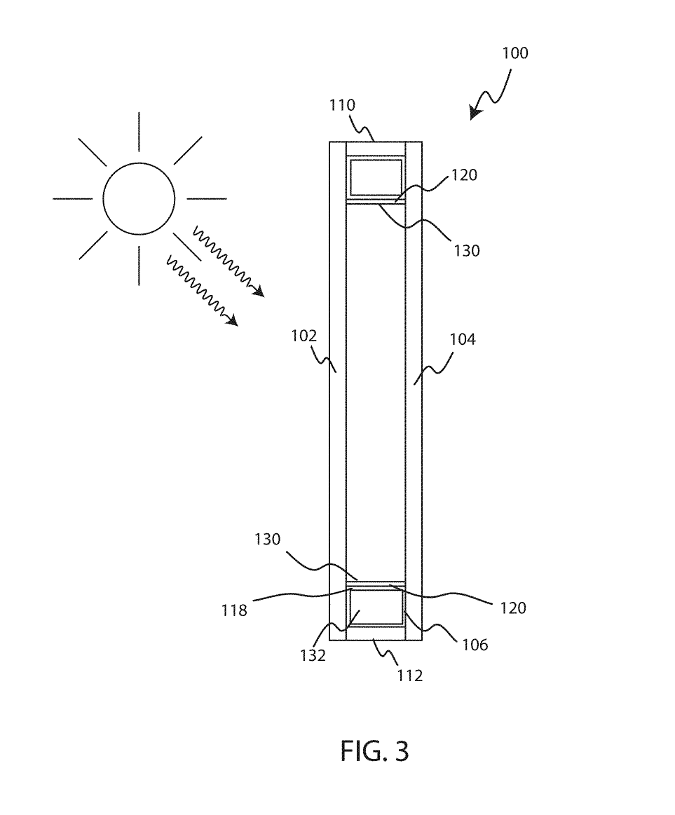

FIG. 3 shows a cross-sectional view of an IGU 100 taken along line 3-3′ in FIG. 2, according to various embodiments. FIG. 3 shows the first pane 102, the second pane 104, the top portion 110 of the IGU 100, and the bottom portion 112 of the IGU 300. FIG. 3 further shows portions of the spacer unit 106, the open inner area 132 of the spacer, and the photovoltaic cell structure 120.

The photovoltaic cell structure 120 can be disposed on the inward surface 118 of the spacer unit 106. In some embodiments, the photovoltaic cell structure 120 is only on the inward surface of the spacer unit 106 and not on the surfaces of the first pane 102 and the second pane 104. The photovoltaically active surface 130 of the photovoltaic cell structure 120 can be substantially perpendicular to the first pane 102 and/or the second pane 104. In various embodiments, the photovoltaically active surface 130 of the photovoltaic cell structure 120 can be substantially parallel with the inward surface 118 of the spacer unit 106. In various embodiments, the photovoltaic cell structure 120 can completely cover the inward surface 118. In some embodiments, the photovoltaic cell structure 120 covers at least about 5, 10, 20, 30, 40, 50, 60, 70, 80, 90, 95, 98, 99 or 100 percent of the surface area of the inward surface 118 of the spacer unit 106. In some embodiments the photovoltaic cell structure 120 covers an amount of the inward surface 118 that falls within a range wherein any of the foregoing percentages can serve as the upper or lower bound of the range, provided that the upper bound is greater than the lower bound. In some embodiments, the photovoltaic cell structure 120 has a width that is at least about 5, 10, 20, 30, 40, 50, 60, 70, 80, 90, 95, 98, 99 or 100 percent of the width of the inward surface 118 of the spacer unit 106. In some embodiments the photovoltaic cell structure 120 has a width that, measured as a percent of the width of the inward surface of the spacer unit, falls within a range wherein any of the foregoing percentages can serve as the upper or lower bound of the range, provided that the upper bound is greater than the lower bound.

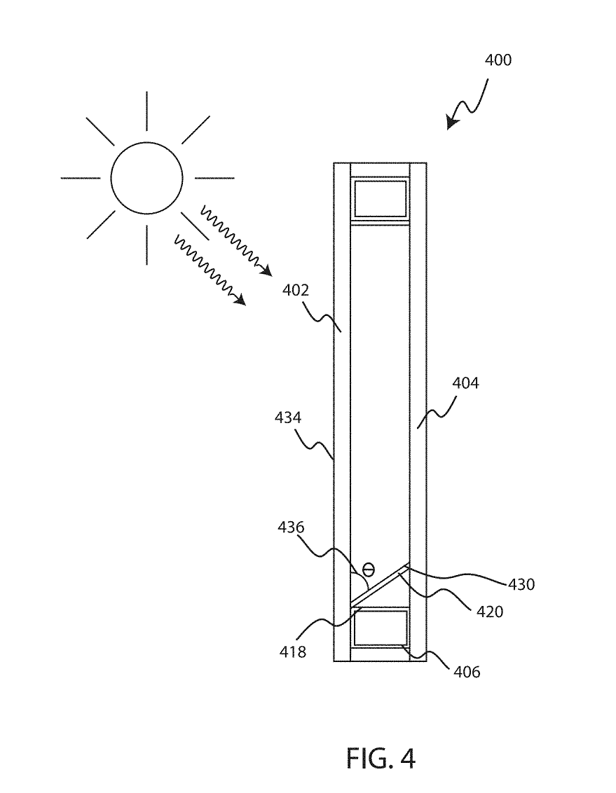

In some embodiments, the photovoltaic cell structure is oriented substantially parallel to the inward surface of the spacer unit. But in other embodiments the photovoltaic cell structure may be tipped towards the inside or the outside. Referring now to FIG. 4, a cross-sectional view of an IGU 400 is shown according to various embodiments. In some embodiments, the photovoltaic cell structure 420 is disposed on the inward surface 418 of the spacer unit 406 oriented such that the photovoltaically active surface 430 is arranged in non-perpendicular and non-parallel configuration with the first pane 402 and the second pane 404. In some embodiments, the photovoltaically active surface 430 is arranged in a non-perpendicular and non-parallel configuration with the inward surface 418 of the spacer unit 406. In various embodiments, the surface area of the photovoltaic cell structure 420 can be greater than or equal to the surface area of the inward surface 418. The photovoltaically active surface 430 can be inclined towards an exterior side 434 of the IGU 400. The exterior side of an IGU can refer to the side of the IGU that will be towards the outside of a building, in contrast to the interior side of an IGU which can refer to the indoor side of the IGU.

In various embodiments, the photovoltaically active surface 430 can be arranged to define an angle 436 of at least 5 degrees and not more than 85 degrees or at least 10 degrees and not more than 80 degrees between the photovoltaically active surface 430 and the first pane 102. In various embodiments, the photovoltaically active surface 430 can be arranged to define an angle 436 of at least 15 degrees and not more than 75 degrees between the photovoltaically active surface 430 and the first pane 102. In various embodiments, the photovoltaically active surface 430 can be arranged to define an angle 436 of about 60 degrees between the photovoltaically active surface 430 and the first pane 402. In various embodiments, the photovoltaically active surface 430 can be arranged to define an angle 436 of about 45 degrees between the photovoltaically active surface 430 and the first pane 402. In various embodiments, the photovoltaically active surface 430 can be arranged to define an angle 436 of about 30 degrees between the photovoltaically active surface 430 and the first pane 402.

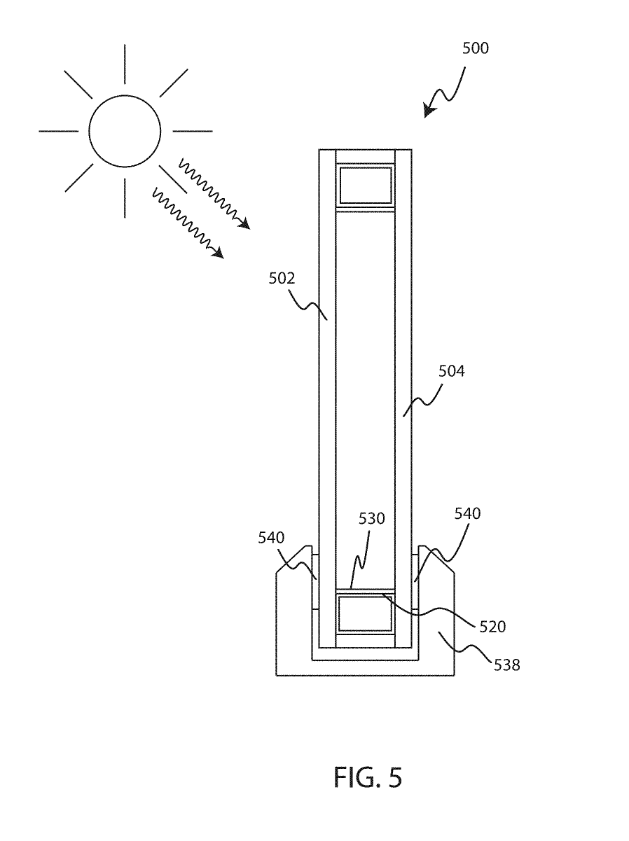

In some embodiments herein, a reflective material can be used on some portions of the IGU or outside the IGU in order to enhance the amount and/or intensity of light that hits the photovoltaic cell structure. FIG. 5 shows a cross-sectional view of an IGU 500 including a portion of a frame or sash 538 according to various embodiments. In various embodiments, the IGU 500 can be at least partially surrounded or enclosed by a sash 538. The sash 538 can surround or enclose the perimeter of the IGU 500.

In some instances, the sash 538 or other features surrounding the IGU can block some light rays from the contacting the photovoltaically active surface 530 of the photovoltaic cell structure 520. Additionally, some light rays that are not blocked by the sash 538 could still miss contacting the photovoltaically active surface 530, such as by contacting inner portions of the sash 538. In some embodiments, a reflective material 540 can be applied to an outer edge of one or both of the panes 502, 504. The reflective material 540 can be configured to reflect light rays towards the photovoltaically active surface 530, such as to increase performance of the photovoltaic cell structure 520 by exposing the photovoltaically active surface 530 to a higher concentration of light rays. Reflective material 540 can be either specularly reflective or diffusely reflective. In some cases, structured Fresnel type reflective surfaces can also be used. While FIG. 5 depicts the reflective material on sides of the panes away from the interior space between the panes (or on the sash or frame itself), it will be appreciated that the reflective material can also be disposed on the interior sides of the panes (e.g., on the pane surfaces contacting the interior space between the panes).

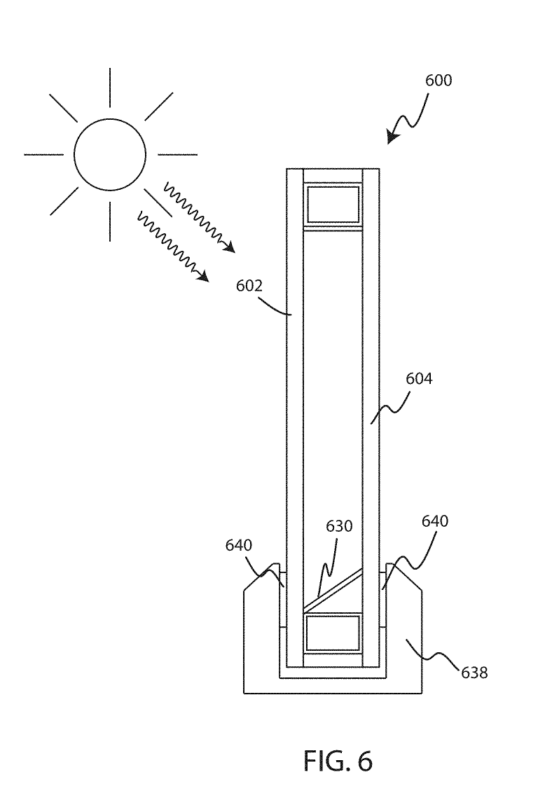

FIG. 6 shows a cross-sectional view of an IGU 600 including a sash 638 according to various embodiments. Similar to the arrangement depicted in FIG. 4, the photovoltaically active surface 630 included in an IGU 600 with a sash 638 can be arranged in a non-perpendicular and non-parallel manner with the panes 602, 604. In various embodiments, the IGU with an inclined photovoltaically active surface 630 can include reflective material 640 applied to an outer edge of one or both of the panes 602, 604.

In addition to, or instead of, a reflective material, in some embodiments a structure such as a light pipe or light guide can be included and can arranged to enhance the amount of light rays hitting the photovoltaic cells. In some embodiments, the exit path of light from the light pipe or light guide can be at or near the photovoltaically active surface of the photovoltaic cell structure.

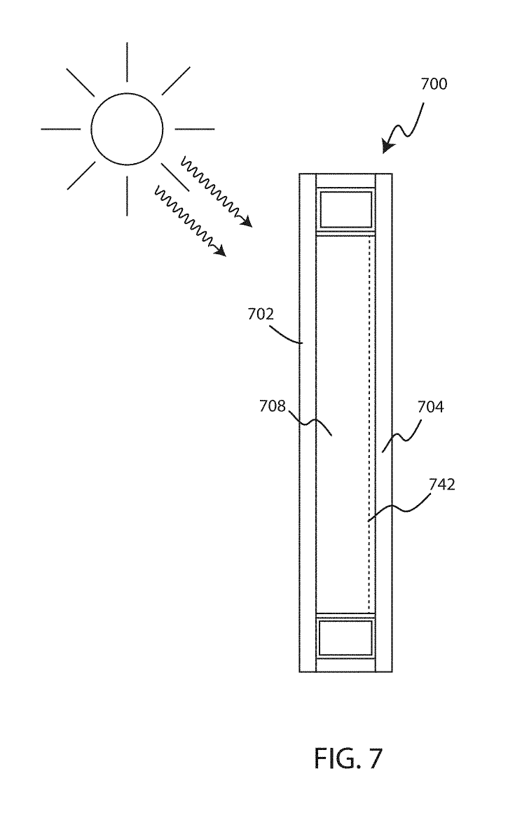

Various embodiments herein can also include a component that requires power. Referring now to FIG. 7, a cross-sectional view is shown of an IGU 700 according to various embodiments. The IGU 700 and/or the products it is incorporated into can include an electricity or power demanding component 742 shown schematically in FIG. 7. In some embodiments, the power demanding component 742 can be disposed within the interior space 708. In some embodiments, the power demanding component 742 can be disposed exterior to the IGU 700, such as on a surface of one of the panes 702, 704.

The power demanding component 742 can be a component which demands electricity in order to perform its desired task. Various embodiments of a power demanding component 742 are discussed below. The power demanding component 742 can be used in accordance with the IGU 700 to provide a more pleasant environment to the area around the IGU 700, such as to control light transmission or limit sound transmission. In other embodiments, the power demanding component 742 can monitor aspects of the IGU 700.

In various embodiments, the insulating glazing unit can further include a joining member (or coupler). The joining member can serve to connect two ends of the spacer unit together. The joining member can also serve as a conduit to provide for the passage of an electrical conductor(s) thereby providing electrical communication between the photovoltaic cell structure and an area outside the spacer unit. The joining member can be placed anywhere along the spacer unit. The joining member can take on various specific constructions and can be formed of various materials. In some embodiments, the joining member can be a tape, foil, or MYLAR material (in some cases with an adhesive layer) that can serve as a connector that can be used to span and/or attach ends of a spacer unit together. In some embodiments, the joining member can be a bridging structure containing receiving sockets into which the ends of the spacer unit can fit and/or tongue structures that can fit into channels or open areas disposed inside of the spacer unit ends.

In some embodiments the joining member can specifically be a corner key that can be connected to a corner of the spacer unit. The corner key can be connected to a first and second electrical conductor providing electrical communication between the photovoltaic cell structure and an area outside the spacer unit.

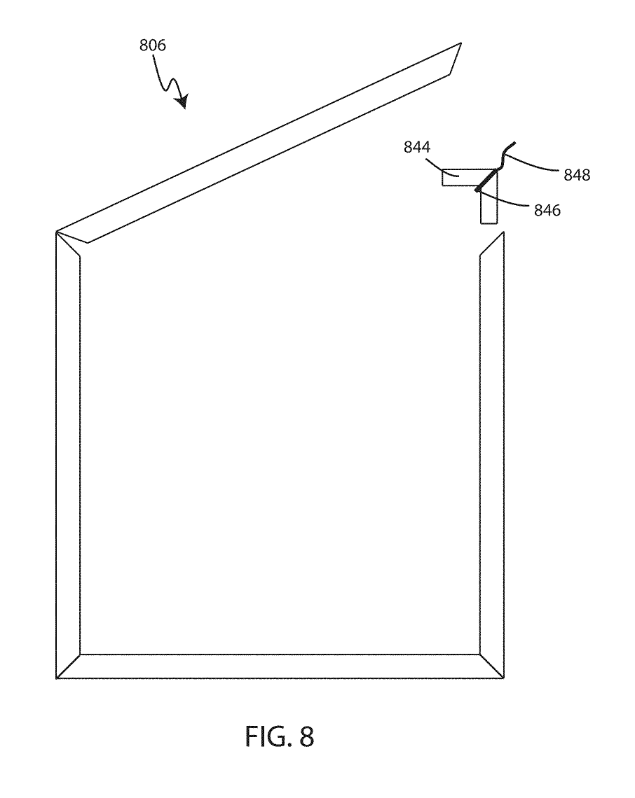

Referring now to FIG. 8, a front view is shown of a spacer unit 806 according to various embodiments. In some embodiments, the spacer unit 806 can define an inner area, such as an area filled with a vapor absorbing desiccant. In some embodiments, a corner key 844 can be used to couple one end of the spacer unit 806 to another end of the spacer unit 806 such as by being inserted into the inner area of each ends of the spacer unit 806. In some embodiments, the corner key 844 can be connected to a corner of the spacer unit 806.

In various embodiments, the corner key 844 can provide electrical communication between the photovoltaic cell structure and an area outside the spacer unit, such as the power demanding component. In some embodiments, the corner key 844 can include a first electrical conductor 846, such as to be coupled to the photovoltaic cell structure. The corner key 844 can further include a second electrical conductor 848, such as to be coupled to the power demanding component. In various embodiments, the electrical conductors 846, 848 can include a spring contact, insulation-piercing blades, wires, or soldered connectors.

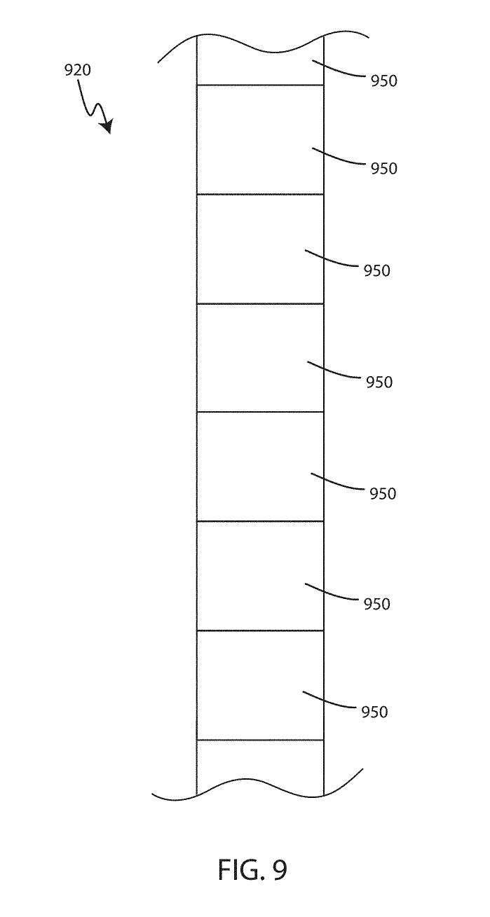

FIG. 9 shows a top view of a portion of a photovoltaic cell structure 920, according to various embodiments. In various embodiments, the photovoltaic cell structure 920 can include a plurality of discrete photovoltaic cells 950. In various embodiments, each photovoltaic cell 950 can generate electricity from light rays that the photovoltaic cell 950 is exposed to. The plurality of discrete cells can be connect in series, in parallel, or in combinations thereof to provide the desired current or voltage output. Photovoltaic cell arrays are commercially available from PowerFilm, Inc. located in Ames, Iowa; Trina Solar, located in Changzhou, China; Canadian Solar, located in Guelph, Canada; JinkoSolar located in Shanghai, China; and JA Solar, located in Shanghai, China; amongst others.

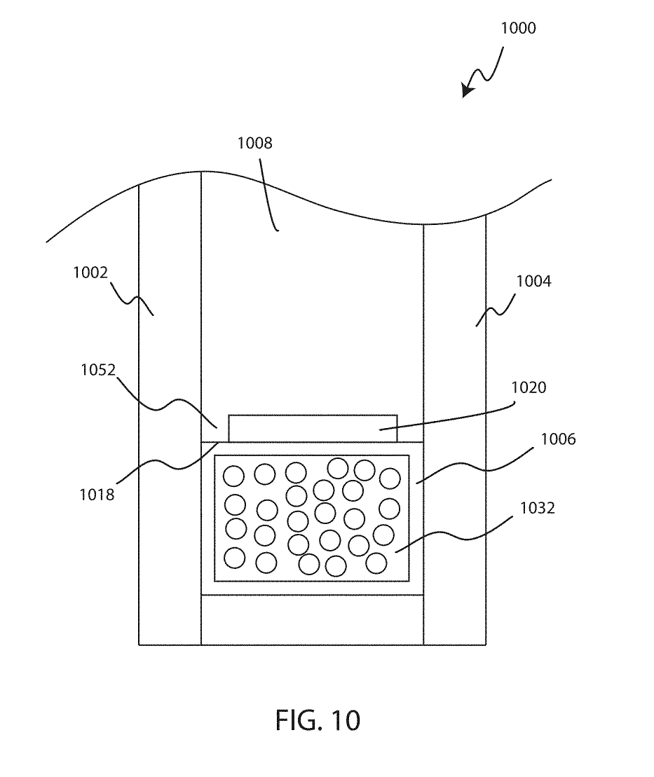

FIG. 10 shows a cross-sectional view of a portion of an IGU 1000, according to various embodiments. In various embodiments, the photovoltaic cell structure 1020 can be disposed substantially equidistantly from the first pane 1002 and the second pane 1004. The photovoltaic cell structure 1020 can be centered on the inward surface 1018 of the spacer unit 1006. In some embodiments, the photovoltaic cell structure 1020 can have a smaller width than the inward surface 1018 of the spacer unit 1006, such as to define a gap 1052. In some embodiments, the gap 1052 can allow the inner open area 1032 of the spacer unit 1006 to be in fluid communication with the interior space 1008 of the IGU 1000, such as to allow a desiccant material within the inner open area 1032 to absorb or otherwise remove vapor from the interior space 1008 (e.g., to allow movement of water vapor from the interior space 1008 to the desiccant material within the inner open area 1032).

While FIG. 10 shows a spacer unit with an inner open area, it will be appreciated that other spacer constructions are contemplated herein. For example, some spacers can be formed of a polymeric material and may lack any substantial inner open area. In such cases, the spacer may lack an outer “shell” or outer layer defining an interior volume. Rather, the spacer may be formed of a substantially solid piece of a polymeric composition. An example of this type of spacer construction is the SUPER SPACER® spacer (commercially available from Quanex Building Products).

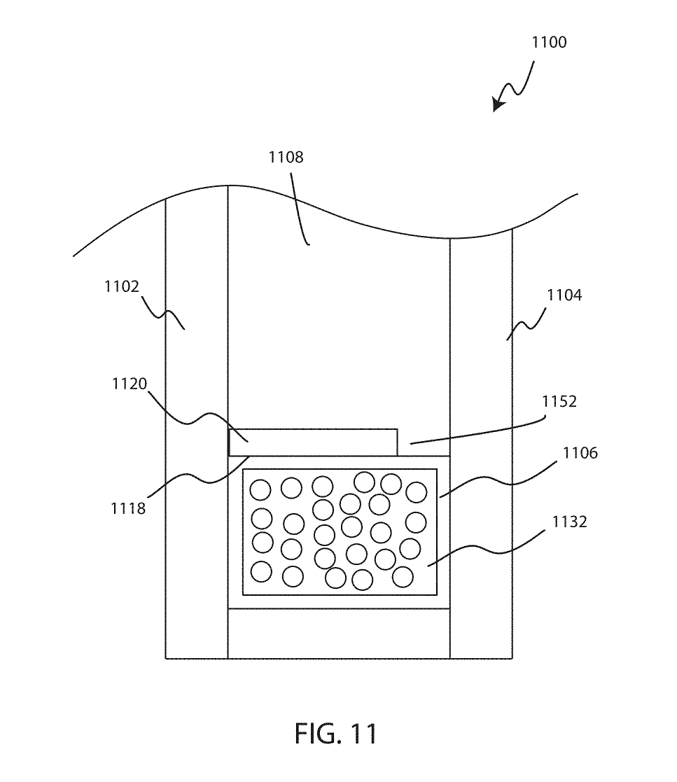

FIG. 11 shows a cross-sectional view of a portion of an IGU 1100, according to various embodiments. In various embodiments, the photovoltaic cell structure 1120 can be disposed closer to one of the first pane 1102 or second pane 1104 than it is to the other pane 1102, 1104. FIG. 11 shows the photovoltaic cell structure 1120 disposed closer to and adjacent to the first pane 1102. The photovoltaic cell structure 1120 can be offset from a centered location on the inward surface 1118 of the spacer unit 1106, such as to define a gap 1152. In the embodiment shown in FIG. 11, the gap 1152 is defined between the photovoltaic cell structure 1120 and the second pane 1104. In some embodiments, the gap 1152 can allow the inner area 1132 of the spacer unit 1106 to be in fluid communication with the interior space 1108 of the IGU 1100.

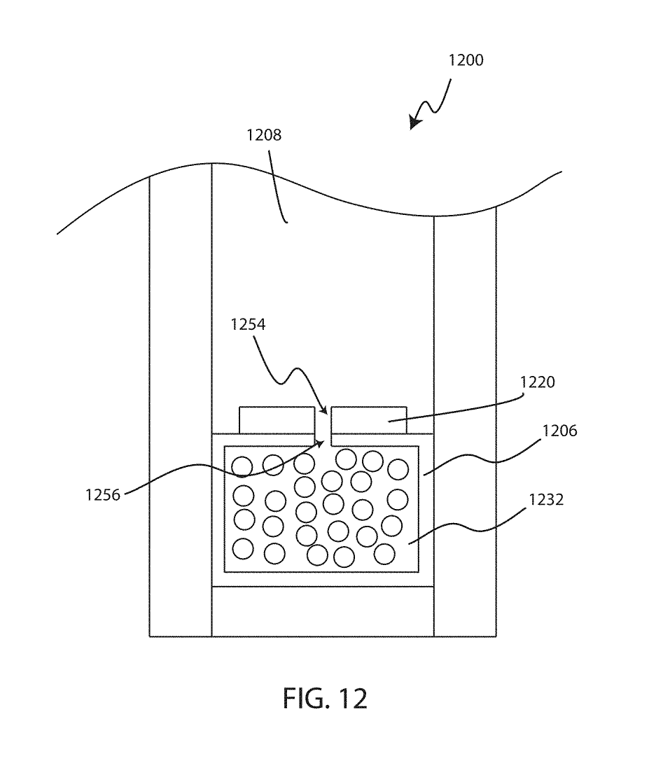

FIG. 12 shows a cross-sectional view of a portion of an IGU 1200, according to various embodiments. In various embodiments, the photovoltaic cell structure 1220 can define a plurality of apertures 1254. The apertures 1254 can be aligned with apertures 1256 in the spacer unit 1206 to allow fluid communication between the interior space 1208 and the inner area 1232 of the spacer unit 1206, such as allow the passage of water vapor there through. In some embodiments, the plurality of apertures 1254 can be defined along a center of the photovoltaic cell structure 1220, such as to align with the apertures 1256 in the spacer unit 1206.

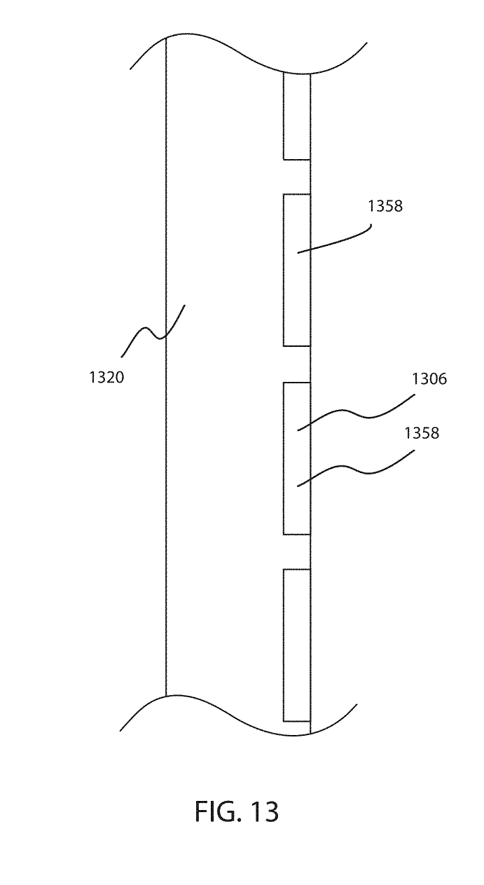

FIG. 13 shows a top view of a photovoltaic cell structure 1320 on a spacer unit 1306, according to various embodiments. In some embodiments, the photovoltaic cell structure 1320 can include cutouts 1358, such as lateral cutouts shown in FIG. 13. The cutouts 1358 can expose portions of the spacer unit 1306, such as to allow fluid communication between the interior space of the IGU and the inner area of the spacer unit 1306.

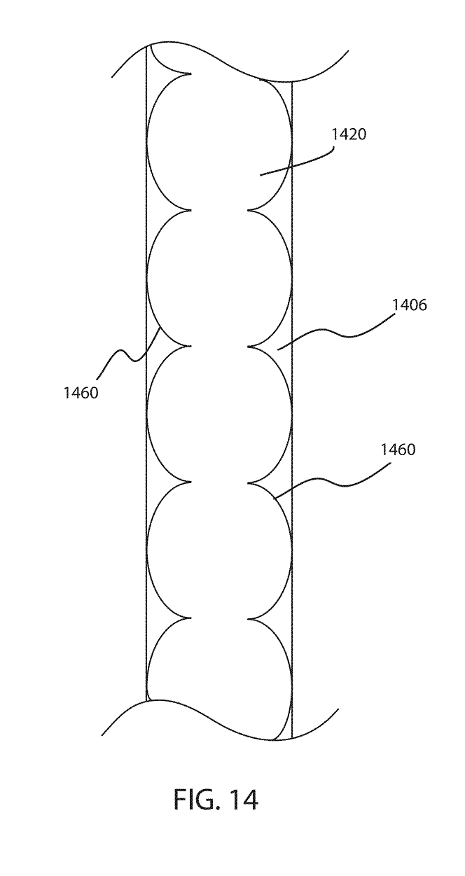

FIG. 14 shows a top view of a photovoltaic cell structure 1420 on a spacer unit 1406, according to various embodiments. In some embodiments, the photovoltaic cell structure 1420 can include scalloped side edges 1460. The scalloped side edges 1460 can provide gaps which can allow fluid communication between the interior space and the inner area of the spacer unit 1406.

The scalloped side edges 1460 can include linear segments (such as shown in FIG. 13), non-linear segments (such as shown in FIG. 14), or both. Further, the scalloped side edges 1460 can be on both sides of the photovoltaic cell structure 1420 (similar to as shown in FIG. 14) or only on one side (similar to as shown in FIG. 13).

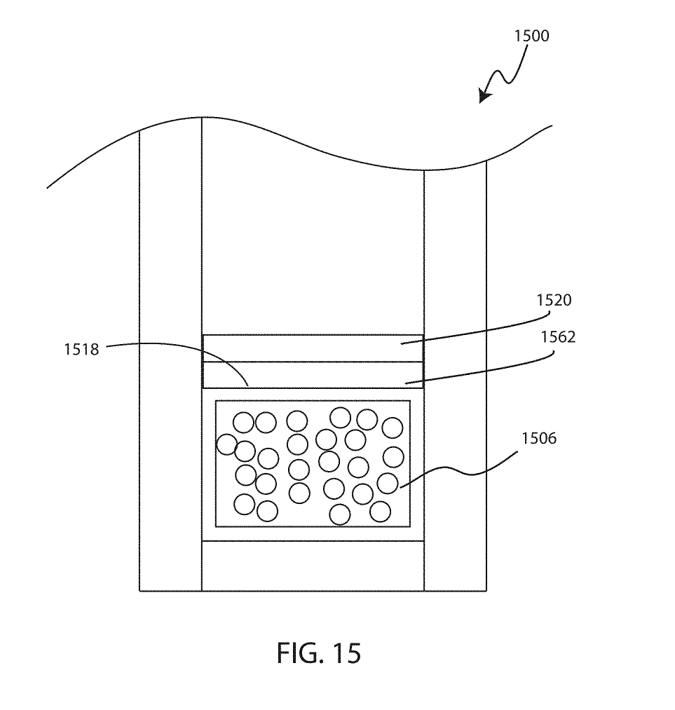

FIG. 15 shows a cross-sectional view of a portion of an IGU 1500, according to various embodiments. In various embodiments, the photovoltaic cell structure 1520 can include a flexible substrate 1562. The flexible substrate 1562 can be attached or coupled to the inward surface 1518 of the spacer unit 1506, thereby attaching the photovoltaic cell structure 1520 to the spacer unit 1506. However, in other embodiments, the flexible substrate 1562 can be omitted and the other components of the photovoltaic cell structure 1520 can be directly or indirectly attached to the inward surface 1518 of the spacer unit 1506 with an adhesive layer or through other techniques such as clips, brackets, screws, standoffs, posts, tabs, bolts or other fasteners, welding (spot, ultrasonic, thermal, etc.), direct deposition or printing, and the like.

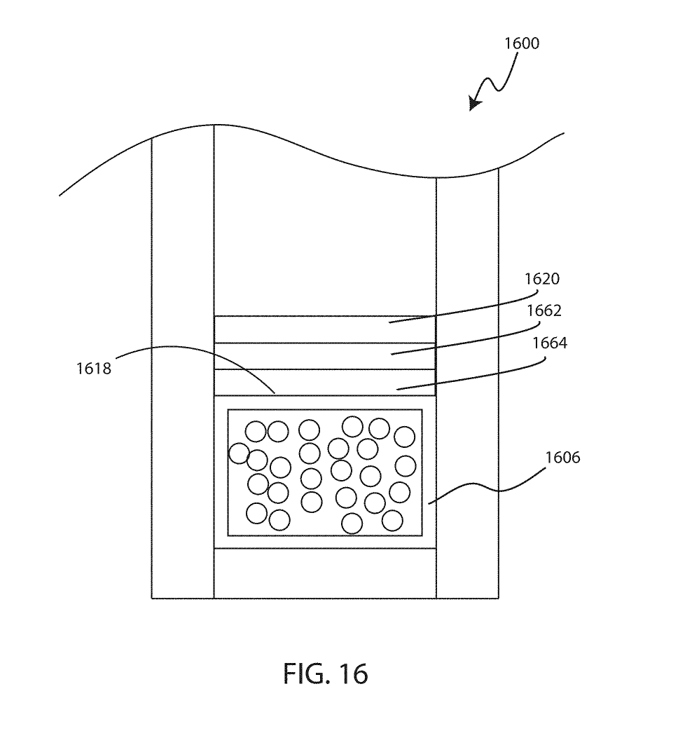

FIG. 16 shows a cross-sectional view of a portion of an IGU 1600, according to various embodiments. In various embodiments, the photovoltaic cell structure 1620 can include a flexible substrate 1662. An adhesive layer 1664 can be disposed between the flexible substrate 1662 and the inward surface 1618 of the spacer unit 1606. The adhesive layer 1664 can couple or attach the flexible substrate 1662 to the inward surface 1618 of the spacer unit 1606. However, in other embodiments, the flexible substrate 1662 can be omitted and the other components of the photovoltaic cell structure 1620 can be directly or indirectly attached to the inward surface 1618 of the spacer unit 1606 with an adhesive layer or through other techniques such as clips, brackets, screws, standoffs, posts, tabs, bolts or other fasteners, welding (spot, ultrasonic, thermal, etc.), direct deposition or printing, and the like.

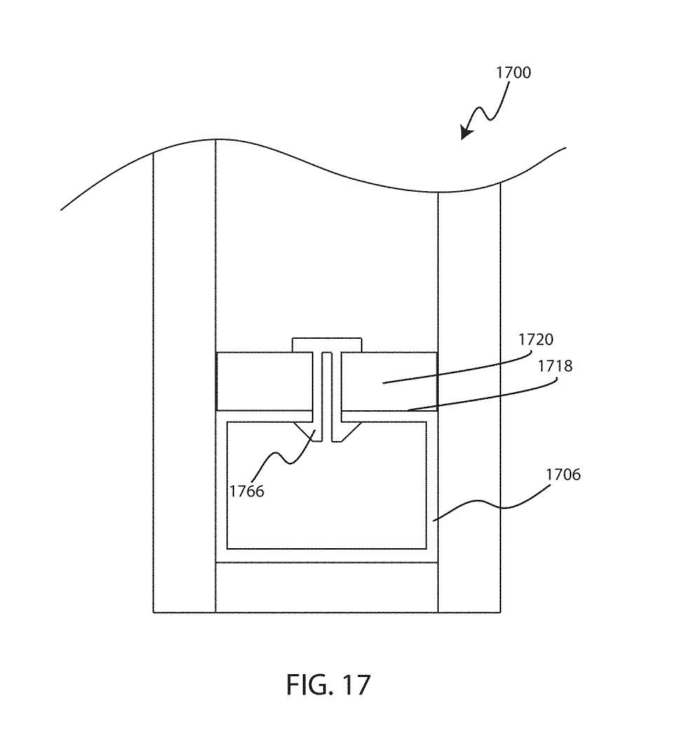

FIG. 17 shows a cross-sectional view of a portion an IGU 1700, according to various embodiments. In some embodiments, the photovoltaic cell structure 1720 can be attached to the inward surface 1718 of the spacer unit 1706 with a clip 1766. In some embodiments, the clip 1766 can extend through the photovoltaic cell structure 1720 and into the spacer unit 1706 to attach the photovoltaic cell structure 1720 to the spacer unit 1706.

In some embodiments, such as shown in FIG. 17, the photovoltaic cell structure (or a component thereof) may be in direct contact with the inward surface of the spacer unit. However, in other embodiments, there may be a gap between the photovoltaic cell structure and the inward surface of the spacer unit. While not intending to be bound by theory, it is believed that there may be significant benefits associated with having a space underneath for electronics and/or for venting to a desiccant in the spacer unit.

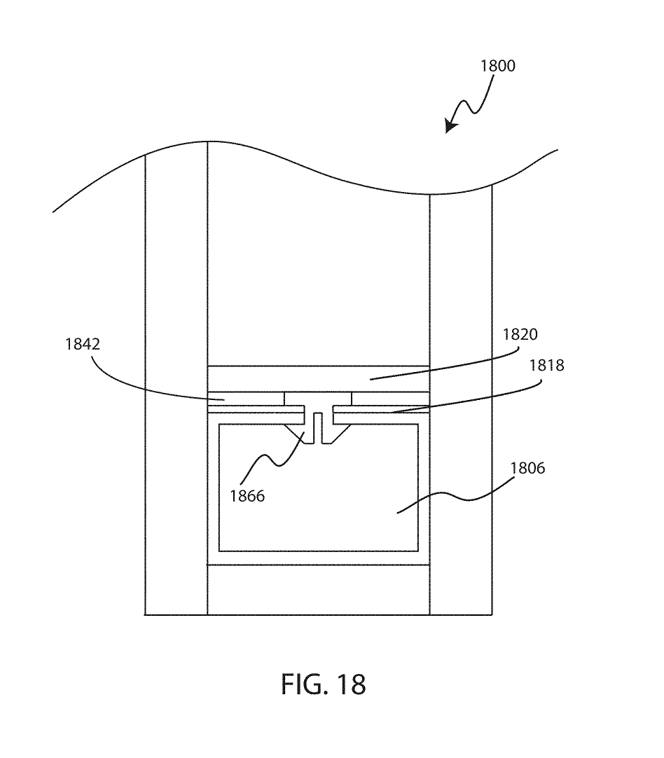

Referring now to FIG. 18, a cross-sectional view of a portion of an IGU 1800, according to various embodiments. In some embodiments, the photovoltaic cell structure 1820 can be attached to the spacer unit 1806 with a clip 1866. In some embodiments, the photovoltaic cell structure 1820 can be attached to the clip 1866, such as a top portion of the clip 1866. The clip 1866 can extend into the spacer unit 1806 to attach the photovoltaic cell structure 1820 to the spacer unit 1806. A gap 1842 is disposed between the photovoltaic cell structure 1820 and the inward surface 1818 of the spacer unit 1806. In some embodiments the gap can be at least about 0.1, 0.2, 0.5, 1, 2, 5, 10, 20, or 30 millimeters. In some embodiments, the gap can be in a range wherein any of the foregoing distances can serve as the upper or lower bound of the range, provided that the upper bound is greater than the lower bound.

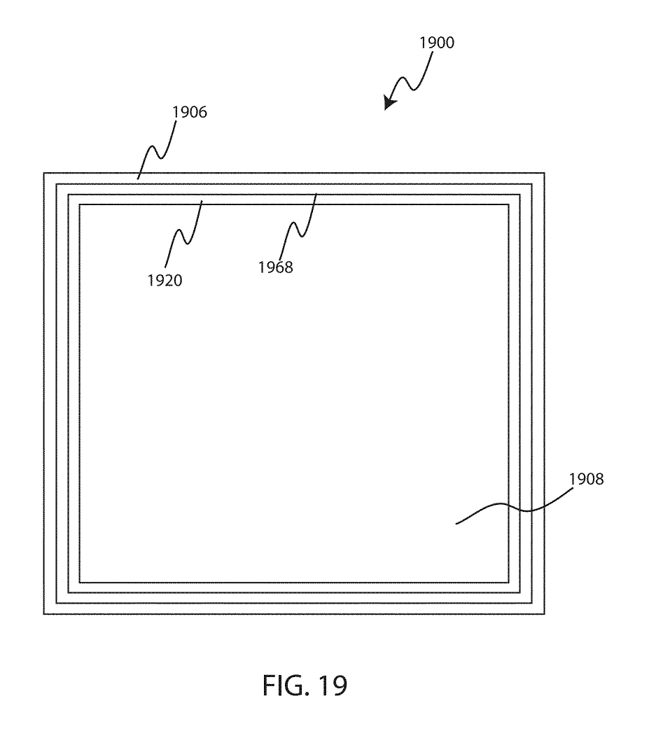

In some embodiments, an interior frame can be disposed within the interior space of the IGU and the interior frame can be used to support the photovoltaic cell structure. FIG. 19 shows a front view of an IGU 1900 with a spacer unit 1906 and photovoltaic cell structure 1920, according to various embodiments. In some embodiments, the IGU 1900 can include a frame 1968. The frame 1968 can be disposed within the interior space 1908 of the IGU 1900. The frame 1968 can be arranged and disposed between the spacer unit 1906 and the photovoltaic cell structure 1920. The photovoltaic cell structure 1920 can be supported by the frame 1968. The frame 1968 can be formed of various materials including metal, ceramic, polymer, composite or the like.

While many embodiments shown herein are depicted with a first transparent pane and a second transparent pane, it will be appreciated that embodiments herein can include glazing units with more than two panes of material (e.g., more than two panes of glass). For example, embodiments herein can also include glazing units with 3 panes of glass and in some cases 4 panes of glass.

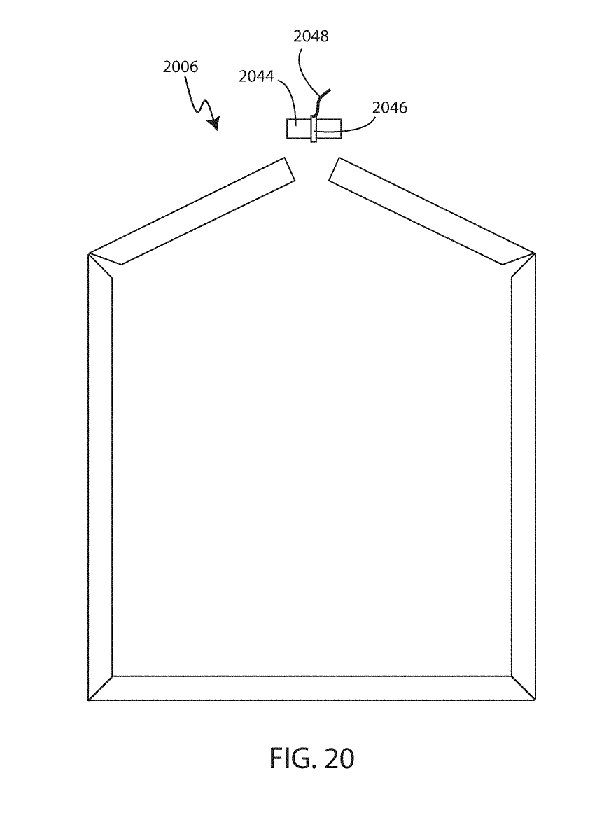

Referring now to FIG. 20, a front view is shown of a spacer unit 2006 according to various embodiments. In some embodiments, the spacer unit 2006 can define an inner area, such as an area filled with a vapor absorbing desiccant. In some embodiments, a joining member 2044 can be used to couple one end of the spacer unit 2006 to another end of the spacer unit 2006 such as by being inserted into the inner area of each end of the spacer unit 2006. In some embodiments, the joining member 2044 can be connected to a midpoint of one side of the spacer unit 2006.

In various embodiments, the joining member 2044 can provide electrical communication between the photovoltaic cell structure and an area outside the spacer unit, such as the power demanding component. In some embodiments, the joining member 2044 can include a first electrical conductor 2046, such as to be coupled to the photovoltaic cell structure. The joining member 2044 can further include a second electrical conductor 2048, such as to be coupled to the power demanding component. In various embodiments, the electrical conductors 2046, 2048 can include a spring contact, insulation-piercing blades, wires, or soldered connectors. It will be appreciated, however, that the joining member can take on many other specific forms as referred to elsewhere herein.

### Electrically Powered Components

Various components that require electricity can be used in combination with an IGU and/or other components of a fenestration unit. These components can be located within or adjacent to the IGU. In various embodiments, the components can include an electrochromic layer for controlling light transmission. In some embodiments, the components can include variable light transmission devices such as liquid crystal devices or suspended particle devices.

In other embodiments, the components can include monitoring devices or sensors, such as to monitor for unwanted intrusions or to monitor environmental conditions. For example the components can include lock position sensors, panel position sensors, or other security sensors. Some of the components can include microprocessors, signal transmitters and receivers, as well as other devices for integrating the IGU into a home automation system or energy management system.

In some embodiments, components including one or more electric motors or components including the same can be disposed within an IGU and/or a product into which an IGU is disposed. In some embodiments, electrically powered components herein can include powered actuation devices such as powered openers, powered screens, powered shades, powered locks and the like.

Components that can be disposed within an IGU and/or a product into which an IGU is disposed can also include power storage components. Power storage components can serve to store electrical energy and then power electrically powered components such as at times when photovoltaic cells produce insufficient electrical power for operation of the electrically powered components. Power storage components can include, but are not limited to, batteries, capacitors, supercapacitors, electrolytic capacitors, power storage circuitry, and the like.

### Photovoltaic Cells and Structure

Photovoltaic cells use light energy (photons) from the sun to generate electricity through the photovoltaic effect. Photovoltaic cells can be formed of various constructions including, but not limited to, wafer-based crystalline silicon cells, thin-film cells, and multi-junction cells. In various embodiments of the photovoltaic cells, the cells can be responsive to or generate electricity from wavelengths of light of at least 380 nm and up to 750 nm. In various embodiments of the photovoltaic cells, the cells can be responsive to or generate electricity from wavelengths of light of no more than 380 nm and above 750 nm.

In various embodiments, the photovoltaic cell structure can be porous to the passage of water vapor, such as to provide fluid communication between the interior space of the IGU and the inner area of the spacer unit. Photovoltaic cell structures that are porous to the passage of water vapor can allow water vapor in the interior space to be absorb by desiccant in the inner area of the spacer unit. Porosity of the photovoltaic cell structure can be achieved in various ways. In some embodiments, the photovoltaic cell structure can include a plurality of apertures therein. In some embodiments, elements of the photovoltaic cell can be made from porous materials, such as porous silicon. Porous silicon structures are described in US2013/0061920, the content of which is herein incorporated by reference.

In some embodiments, the photovoltaic cell structure can be flexible. A flexible photovoltaic cell structure can be bent or formed into the desired configuration. In one example the photovoltaic cell structure can be in a linear strip and then, during the manufacturing process, bent or formed into a rectangle similarly to the panes. In some embodiments, the photovoltaic cell structure can be bent to a radius of curvature of 1 cm or less without damage. However, in other embodiments, the photovoltaic cell structure can be rigid.

In some embodiments, the photovoltaic cell structure can include a photovoltaic array, such as from PowerFilm®, Inc. located in Ames, Iowa.

### Transparent Panes

The transparent panes of embodiments herein can be made of various materials. In some embodiments, the transparent pane can be a glass material. Glasses can include annealed glasses, heat-strengthening glasses, tempered glasses, laminated glasses and the like. Glass materials can include silica glasses, including but not limited to soda lime glass, fused silica glass, borosilicate glass, alumino-silicate glass, alumino-borosilicate glass and the like.

Glass materials can include both coated and uncoated glass materials. Various coatings can be applied to glass materials in order to provided desired functional properties. In some embodiments, a coating can be applied in order to reduce the emissivity of the glass (Low-E glass). In some embodiments coatings can be applied to provide tinting, reflection, impact resistance, and the like.

The thickness of each transparent pane can vary. In some embodiments, the thickness can be about 1.0, 1.5, 2.0, 2.2, 2.4, 2.6, 2.8, 3.0, 3.2, 3.4, 3.6, 3.8, 4.0, 4.2, 4.4, 4.6, 4.8, 5.0, 5.5, 6.0 millimeters or more. In some embodiments, the thickness can be in a range wherein any of the foregoing thicknesses can serve as the upper or lower bound of the range, provided that the upper bound is greater than the lower bound.

### Spacers

Many different spacers are contemplated herein. Exemplary spacers can include, but are not limited to, SUPER SPACER® spacers (commercially available from Quanex Building Products), XL EDGE® spacers (commercially available from Cardinal Glass), INTERCEPT® spacers (commercially available from GED Integrated Solutions), SWIGGLE® seal spacers (commercially available from Quanex Building Products), ENDUR-IG® spacers (commercially available from Cardinal Glass), TECHNOFORM spacers (commercially available from Caprano and Brunnhofer GmbH), multitech spacers (commercially available from Rolltech A/S), chromatech spacers (commercially available from Rolltech A/S), ferrotech spacers (commercially available from Rolltech A/S), aluminum box spacers, stainless steel spacers, polymeric spacers, and the like.

Spacers can have many different widths. In some embodiments, the width of the spacer can be about 3, 4, 5, 5.5, 6.5, 7, 7.5, 8, 8.5, 9, 9.5, 10, 10.5, 11, 11.5, 12, 12.2, 12.5, 13, 14, 14.5, 15, 16, 18, 24, or 30 millimeters. In some embodiments, the width of the spacer can be in a range wherein any of the foregoing widths can serve as the upper or lower bound of the range, provided that the upper bound is greater than the lower bound.

In some embodiments, spacers herein can include desiccants. In various embodiments herein, glazing units can include desiccants. Desiccants can be disposed adjacent to window spacers or within channels or pockets formed by window spacers in various embodiments. In some embodiments, desiccants can be disposed within window spacer assemblies such as dispersed within polymers used to make window spacer assemblies. The desiccant can be any conventional desiccant material including, but not limited to, molecular sieve and silica gel type desiccants, desiccated foams, or combinations thereof.

### Reflective Surfaces

In some embodiments, reflective surfaces herein can be formed with a material that exhibits specular or diffuse reflection. In some embodiments, the reflective surfaces can include a reflective film. In some embodiments, the reflective surfaces can include a foil, such as a layer of a metal or a metal oxide. In some embodiments, the reflective surfaces can include a sealant with white pigment or reflective fillers to increase the amount of light rays directed at the photovoltaic cell structure. In other embodiments, the reflective surface can include a laminate or other sheet like product that is adhered to a surface to reflect light from the surface.

### Methods

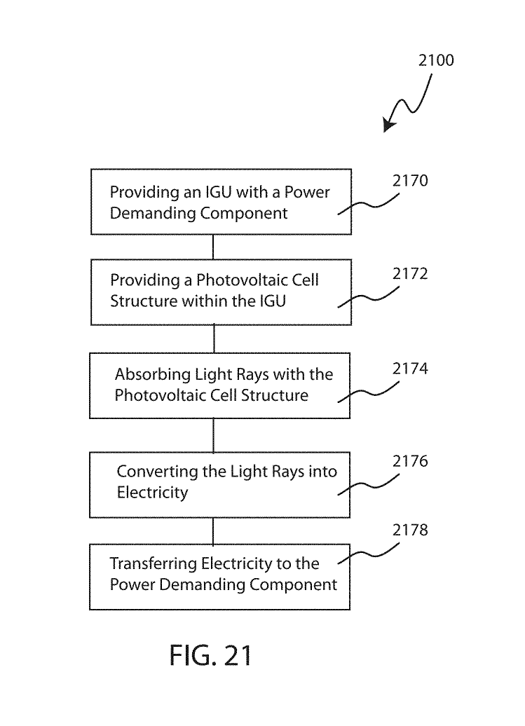

Various embodiments include a method 2100 for providing electricity to a power demanding component within an IGU. Referring now to FIG. 21, a schematic diagram is shown of one embodiment of how electricity can be delivered to a power demanding component within an IGU.

The IGU can be provided with a power demanding component 2170. The power demanding component 2170 can require electricity to perform its desired function. The IGU can be provided with a photovoltaic cell structure within the IGU 2172. The photovoltaic cell structure can produce electricity for the power demanding component. The photovoltaic cell can absorb light rays 2174, such as from the sun. The photovoltaic cell structure can convert the light rays into electricity 2176. The electricity can be transferred to the power demanding component 2178, such that the power demanding component can be powered to perform its desired task. In some embodiments the electricity can be stored in one or more power storage components. Aspects of exemplary power storage components are described above.

All publications and patents mentioned herein are hereby incorporated by reference. The publications and patents disclosed herein are provided solely for their disclosure. Nothing herein is to be construed as an admission that the inventors are not entitled to antedate any publication and/or patent, including any publication and/or patent cited herein.

It should be noted that, as used in this specification and the appended claims, the singular forms “a,” “an,” and “the” include plural referents unless the content clearly dictates otherwise. Thus, for example, reference to a composition containing “a compound” includes a mixture of two or more compounds. It should also be noted that the term “or” is generally employed in its sense including “and/or” unless the content clearly dictates otherwise.

It should also be noted that, as used in this specification and the appended claims, the phrase “configured” describes a system, apparatus, or other structure that is constructed or configured to perform a particular task or adopt a particular configuration to. The phrase “configured” can be used interchangeably with other similar phrases such as arranged and configured, constructed and arranged, constructed, manufactured and arranged, and the like.

Aspects have been described with reference to various specific and preferred embodiments and techniques. However, it should be understood that many variations and modifications may be made while remaining within the spirit and scope herein. As such, the embodiments described herein are not intended to be exhaustive or to limit the invention to the precise forms disclosed in the following detailed description. Rather, the embodiments are chosen and described so that others skilled in the art can appreciate and understand the principles and practices.

1. An insulating glazing unit comprising:
a first transparent pane;
a second transparent pane;
an internal space disposed between the first and second transparent panes;
a spacer unit disposed between the first and second transparent panes, the spacer unit disposed adjacent the perimeter of the first transparent pane and the second transparent pane, the spacer unit having an inward surface facing the internal space; and
a photovoltaic cell structure disposed between the first and second transparent panes, the photovoltaic cell structure disposed over at least a portion of the inward surface of the spacer unit, the photovoltaic cell structure comprising a photovoltaically active surface facing the internal space.

2. The insulating glazing unit of claim 1, the insulating glazing unit comprising a top, a bottom, a first side and a second side; wherein the photovoltaic cell structure comprises a top portion adjacent the top of the insulating glazing unit, a bottom portion adjacent the bottom of the insulating glazing unit, a first side portion adjacent the first side of the insulating glazing unit, and a second side portion adjacent the second side of the insulating glazing unit.

3. The insulating glazing unit of claim 1, the photovoltaic cell structure comprising a plurality of discrete photovoltaic cells.

4. The insulating glazing unit of claim 1, the photovoltaic cell structure disposed on the inward surface of the spacer unit oriented with the photovoltaically active surface substantially perpendicular to the first transparent pane and the second parent pane.

5. The insulating glazing unit of claim 1, the photovoltaic cell structure disposed on the inward surface of the spacer unit oriented with the photovoltaically active surface both non-perpendicular and non-parallel to the first transparent pane and the second transparent pane.

6. The insulating glazing unit of claim 1, the photovoltaic cell structure disposed substantially equidistantly from the first and second transparent panes.

7. The insulating glazing unit of claim 1, the photovoltaic cell structure disposed closer to one of the first and second transparent panes than the other.

8. The insulating glazing unit of claim 4, wherein the plurality of discrete photovoltaic cells are responsive to wavelengths of light between 380 nm and 750 nm.

9. The insulating glazing unit of claim 4, wherein the plurality of discrete photovoltaic cells are responsive to wavelengths of light below 380 nm and above 750 nm.

10. The insulating glazing unit of claim 1, wherein the photovoltaic cell structure is porous to the passage of water vapor.

11. The insulating glazing unit of claim 1, the photovoltaic cell structure comprising a plurality of apertures to allow the passage of water vapor there through.

12. The insulating glazing unit of claim 11, the plurality of apertures disposed along a center of the spacer unit.

13. The insulating glazing unit of claim 1, the photovoltaic cell structure comprising lateral cutouts.

14. The insulating glazing unit of claim 1, the photovoltaic cell structure comprising scalloped side edges.

15. The insulating glazing unit of claim 1, wherein the photovoltaic cell structure is flexible.

16. The insulating glazing unit of claim 1, wherein the photovoltaic cell structure can be bent to a radius of curvature of 1 cm or less without damage.

17. The insulating glazing unit of claim 1, wherein the photovoltaic cell structure is attached to the inward surface of the spacer unit.

18. The insulating glazing unit of claim 1, the photovoltaic cell structure further comprising a flexible substrate, wherein the flexible substrate is attached to the inward surface of the spacer unit.

19. The insulating glazing unit of claim 1, the photovoltaic cell structure further comprising a flexible substrate, wherein the flexible substrate is attached to the inward surface of the spacer unit with an adhesive layer.

20. The insulating glazing unit of claim 1, wherein the photovoltaic cell structure is attached to the inward surface of the spacer unit with a clip.

21. The insulating glazing unit of claim 1, further comprising a frame disposed within the internal space and arranged between the spacer unit and the photovoltaic cell structure; the photovoltaic cell structure supported by the frame.

22. The insulating glazing unit of claim 1, further comprising a joining member that joins a first end and a second end of the spacer unit, the joining member connected to a first and second electrical conductor providing electrical communication between the photovoltaic cell structure and an area outside the spacer unit.

23. The insulating glazing unit of claim 1, the joining unit comprising a corner key, the corner key connected to a corner of the spacer unit.

24. A fenestration unit comprising:
an insulating glazing unit mounted within a frame, the insulating glazing unit comprising:
a first transparent pane;
a second transparent pane;
an internal space disposed between the first and second transparent panes;
a spacer unit disposed between the first and second transparent panes, the spacer unit disposed adjacent the perimeter of the first transparent pane and the second transparent pane, the spacer unit having an inward surface facing the internal space; and
a photovoltaic cell structure disposed between the first and second transparent panes, the photovoltaic cell structure disposed over at least a portion of the inward surface of the spacer unit, the photovoltaic cell structure comprising a photovoltaically active surface facing the internal space.
